(19) United States
(12) Patent Application Publication
(10) Pub. No.: US 2014/0099176 A1
(43) Pub. Date: Apr. 10, 2014

(54) VACUUM PROCESSING APPARATUS AND VACUUM PROCESSING METHOD

(71) Applicant: HITACHI HIGH-TECHNOLOGIES CORPORATION, Tokyo (JP)

(72) Inventors: Keita NOGI, Tokyo (JP); Teruo NAKATA, Tokyo (JP); Kenji TAMAI, Tokyo (JP); Michinori KAWAGUCHI, Tokyo (JP); Yoshiro SUEMITSU, Tokyo (JP)

(73) Assignee: HITACHI HIGH-TECHNOLOGIES CORPORATION, Tokyo (JP)

(21) Appl. No.: 14/023,874

(22) Filed: Sep. 11, 2013

(30) Foreign Application Priority Data
Oct. 10, 2012 (JP) 2012-224685

(51) Int. Cl. H01L 21/677

(52) U.S. Cl. CPC H01L 21/677; H01L 21/67703; H01L 21/67739
USPC 414/217; 414/805

(57) ABSTRACT

A semiconductor processing apparatus is provided, which includes processing chambers coupled together by transport mechanisms having transfer robots. After having completed wafer processing in each processing chamber, the allowable value of a time permitted for a processing-completed wafer to continue residing within the processing chamber is set up. Then, a time consumed up to the completion of transportation of a wafer scheduled to be next processed is estimated, thereby controlling a transfer robot in a way such that, when the estimated transfer time exceeds the allowable value of the waiting time, priority is given to an operation for unloading a processed wafer from the processing chamber insofar as the processed wafer's transfer destination is already in its state capable of accepting such wafer.

### INCORPORATION BY REFERENCE

The present application claims priority from Japanese application JP2012-224685 filed on Oct. 10, 2012, the content of which is hereby incorporated by reference into this application.

### BACKGROUND OF THE INVENTION

The present invention relates generally to a vacuum processing apparatus and, more particularly, to a method for transporting a semiconductor object to be processed (referred to as “wafer” hereinafter) between processing chambers of a semiconductor processing apparatus.

In a semiconductor processing apparatus, in particular, an apparatus for processing objects to be processed in its pressure-reduced interior space, it has been required to improve the efficiency of processing of to-be-processed objects, e.g., wafers, along with miniaturization and high precision of such processing. To this end, in recent years, multiple-chamber apparatus having a plurality of processing chambers coupled to one apparatus has been developed to increase the efficiency of productivity per installation area of a cleanroom. In such apparatus of the type having a plurality of processing chambers to perform wafer processing, each chamber is adjusted to enable an internal gas to decrease in pressure and, simultaneously, is coupled to a transfer chamber having a robot or the like for performing wafer transportation.

In the multi-chamber apparatus of the type stated above, there is widely used an apparatus having a structure called the cluster tool, wherein several processing chambers are radially provided and connected around a transfer chamber. However, this cluster-tool apparatus requires a large installation area. In particular, it suffers from a problem which follows: with the trend of wafer diameter expansion in recent years, the installation area increases more and more. To solve this problem, an apparatus with a structure called the linear tool has appeared (for example, see JP-T-2007-511104 and its corresponding US Patent Publication No. 2012/014769). One major feature of the linear tool lies in the following structure: it has a plurality of transfer chambers, each of which is associated with a processing chamber coupled thereto; and, the transfer chambers are serially connected together with a delivery/receipt space (referred to hereinafter as “intermediate chamber”) being placed between adjacent ones of the transfer chambers.

While the structure called the linear tool has been proposed in order to lessen the installation area in this way, several proposals concerning improvement of productivity have been made until today. To improve the productivity, reduction of the processing time and enhancement of transportation efficiency are important. Especially, regarding efficient transport methodology, many proposals have been made. As one representative method, a scheduling-based method is well-known. The scheduling-based method is the one that performs transportation based on a predetermined wafer transfer operation.

Examples of a transfer operation determination scheme include a method for calculating the productivity such as for example a throughput per transfer order of each processing chamber and for selecting from among them a transfer order with the highest productivity (see JP-A-2011-124496 and its corresponding US Patent Publication No. 2011/144792) and a method for determining a transport operation based on transport operation control rules for changing and updating a number of times of transportation operations in accordance with the layout of processing chambers (see JP-A-2011-181750 and its corresponding US Patent Publication No. 2011/218662).

### SUMMARY OF THE INVENTION

Generally, the processing time of etching, film fabrication or like process differs depending on products; the transportation time also varies by the layout of processing chambers. In this respect, the above-stated methods are those capable of achieving high productivities even in cases where the processing time and transportation time are different. However, in view of the fact that wafers are conveyed by transfer robots, the following event can often occur in reality: while a wafer occupies a transfer robot, other wafers must wait for the transfer robot becoming usable. In such situation, it will possibly happen that the exclusive use of the transfer robot forces a wafer with its processing having been completed in a certain processing chamber to wait long within the processing chamber even after completion of the processing. If this is the case, the dust created during processing can fall onto the wafer, resulting in the wafer becoming higher in the risk of contamination. The above-stated prior art techniques are faced with problems given below.

Even when an attempt is made to reassemble a transportation schedule for determination of each wafer's transfer destination and transfer sequency in order to alleviate deterioration of productivity, one or some transportation methods using transfer robots experience unwanted increase in length of a time taken for a wafer to occupy a transfer robot, resulting in the risk of wafer contamination becoming higher.

It is therefore an object of the present invention to provide a semiconductor processing apparatus which inhibits wafer contamination within processing chambers otherwise occurring due to an increase in length of a time taken for a wafer with its processing being completed in a processing chamber to continue residing and waiting within the processing chamber due to the occupation of a transfer robot by another wafer after completion of the processing in a linear tool.

According to an aspect of the present invention, there is provided with a vacuum processing apparatus including:
a load lock for loading into a vacuum side an object to be processed which is put on an atmosphere side;
a plurality of transport mechanism units, disposed on the vacuum side, each including a vacuum robot for performing delivery/receipt and transportation of the object to be processed;
a plurality of processing chambers coupled to the plurality of transport mechanism units, for applying predetermined processing to the object to be processed;
an intermediate chamber for coupling adjacent ones of the transport mechanism units and for relaying and mounting the object to be processed;
a retention mechanism unit provided in the load lock and the intermediate chamber, for holding a plurality of objects to be processed; and
a control unit for controlling delivery/receipt and transportation of the object to be processed, wherein
the control unit determines a transfer chamber which transfers the object to be processed and an operation order of the transport mechanism units based on a time permitted for the to-be-processed object to wait within one of the processing chambers after completion of processing thereof.

Preferably, the control unit calculates by simulation a processing throughput of the to-be-processed object and determines based on this throughput both the transfer chamber which transfers the to-be-processed object and the operation order of the transport mechanism units.

Preferably, in cases where it is possible to unload the to-be-processed object sooner than the time permitted for the to-be-processed object to wait within the processing unit after completion of its processing, when a processing-completed to-be-processed object which is one of the to-be-processed objects is present within the processing chamber and when, in a transport mechanism unit coupled to this processing chamber, a to-be-processed object which remains unprocessed and whose next transfer destination is this processing chamber exists within the intermediate chamber coupled to the transport mechanism unit, the control unit unloads the to-be-processed object which remains unprocessed while giving priority thereto over the processing-completed to-be-processed object staying within the processing chamber.

Preferably, the control unit estimates a time taken for transfer to the processing chamber and, in cases where the estimated transfer time exceeds the allowable value of the waiting time of the to-be-processed object with its processing completed, causes the transport mechanism unit to prioritize unloading of the to-be-processed object with its processing completed over unloading of the to-be-processed object remaining unprocessed as far as a chamber which is the next transfer destination of the to-be-processed object is in a state capable of accepting the to-be-processed object.

Preferably, regarding the operation order of the plurality of transport mechanism units, the control unit calculates a time taken for the to-be-processed object to wait within the processing chamber after completion of its processing and selects an operation order of the transport mechanism units which prevents the calculated time from exceeding the time permitted for the to-be-processed object to wait within the processing chamber after completion of its processing.

According to this invention, it is possible to provide a semiconductor processing apparatus which prevents contamination of a processing-completed wafer occurring due to an increase in length of a time taken to wait within processing chamber.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram schematically showing an overall configuration of a semiconductor processing apparatus.

FIG. 2 is a diagram showing a structure of machinery part of the semiconductor processing apparatus.

FIG. 3 is a diagram showing a wafer retention structure of the machinery part of the semiconductor processing apparatus.

FIG. 4 is a diagram showing an entire flow of an operation control system of the semiconductor processing apparatus.

FIG. 5 is a diagram for explanation of operation command calculation processing and input/output information.

FIG. 6 is a diagram showing detailed computation processing of estimated time computation.

FIGS. 7A and 7B are diagrams each showing a Gantt chart of transportation operation.

FIG. 8 is a diagram for explanation of transfer destination determination calculation and input/output information.

FIG. 9 is a diagram showing detailed calculation processing of assigned target processing chamber calculation.

FIG. 10 is a diagram showing detailed calculation processing of assigned target processing chamber computation.

FIG. 11 is a diagram showing an example of a display screen of console terminal.

FIG. 12 is a diagram showing an example of apparatus status information.

FIG. 13 is a diagram showing an example of transfer destination information.

FIG. 14 is a diagram showing an example of operation instruction rule information.

FIG. 15 is a diagram showing an example of operation instruction information.

FIG. 16 is a diagram showing an example of operation time information.

FIG. 17 is a diagram showing an example of estimated time information.

FIG. 18 is a diagram showing an example of allowable value information.

FIG. 19 is a diagram showing an example of operation order information.

FIG. 20 is a diagram showing an example of operation sequence information.

FIG. 21 is a diagram showing an example of processing chamber information.

FIG. 22 is a diagram showing an example of assigned target processing chamber information.

FIG. 23 is a diagram showing an example of processing object information.

### DETAILED DESCRIPTION OF THE EMBODIMENT

A currently preferred embodiment of the present invention will now be described with reference to the accompanying figures of the drawing below.

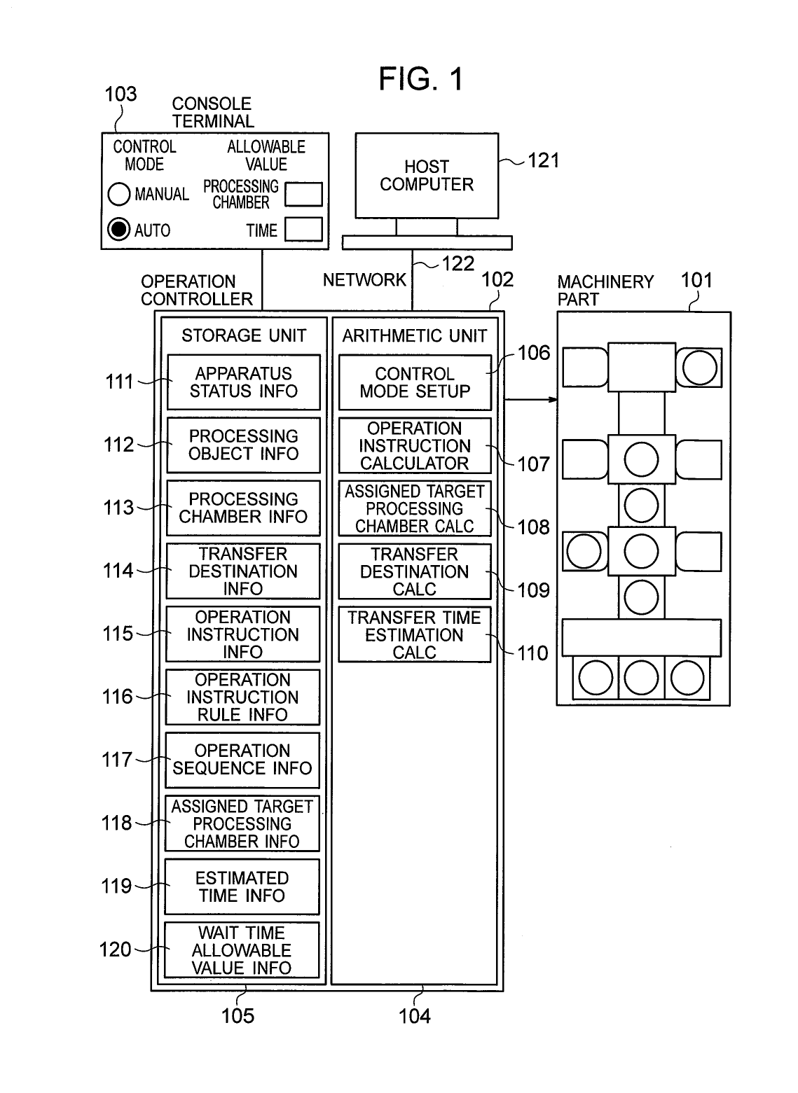

An entire configuration of a semiconductor processing apparatus incorporating the principles of this invention will be set forth with reference to FIG. 1. The semiconductor processing apparatus is generally made up of a machinery part 101 including processing chambers and its associated transport mechanism, an operation control unit 102, and a console terminal 103. The machinery part 101 is constituted from processing chambers capable of applying processing, such as etching, film formation, etc., to wafers, and a transport mechanism having robots for performing wafer transportation. The operation control unit 102 is a controller which controls operations of the processing chambers and transport mechanism. This controller is configured from an arithmetic operation unit 104 which performs arithmetic processing and a storage unit 105 which stores therein various kinds of information or data. The operation unit 104 includes a control mode setup unit 106 which switches the internal processing of a control system in response to receipt of a user's instruction specifying either a “manual” control mode or “automated” control mode, an operation instruction calculation unit 107 which performs arithmetic computation for actually operating the processing chambers and transport mechanism, an assigned target processing chamber calculation unit 108 which computes a processing chamber that becomes a candidate for the transfer destination of a newly loaded wafer, a transfer destination calculation unit 109 which computes the transfer destination processing chamber of a newly loaded wafer, and a transfer time estimation calculation unit 110 which estimates, with respect to each processing chamber, a transfer time consumed up to completion of transfer of a wafer scheduled to be next processed. The storage unit 105 stores therein several kinds of information including apparatus status information 111, processing object information 112, processing chamber information 113, transfer destination information 114, operation instruction information 115, operation instruction rule information 116, operation sequence information 117, assigned target processing chamber information 118, estimated transfer time information 119, and waiting time allowable value information 120. The console terminal 103 is for allowing the user to input a control method and to confirm a present status of the apparatus, wherein this terminal is equipped with a data entry device, such as a keyboard, mouse and/or touch pen, and a display screen for output of information. Additionally, the semiconductor processing apparatus is operatively connected to a host computer 121 via a network 122 and is able to download from the host computer 121 any necessary information when the need arises, which information typically includes a recipe indicating the kind of a gas used for wafer treatment along with its concentration and a standard time required for the treatment.

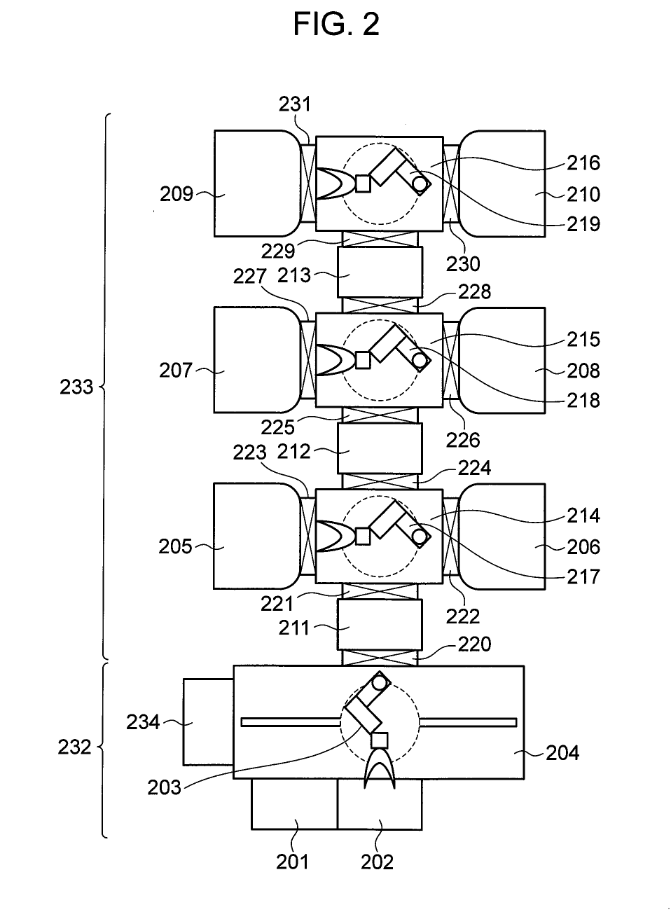

An explanation will next be given, using FIG. 2, of a structure of the machinery part including processing chambers and its associated transport mechanism. FIG. 2 is a diagram depicting a top plan view of the machinery part. This machinery part is generally divided into an atmosphere-side machinery unit 232 and a vacuum-side machinery unit 233. The atmosphere-side machinery unit 232 is a part which performs wafer transportation and its related operations, such as taking a wafer out of a cassette receiving therein wafers and putting a wafer(s) in the cassette under atmospheric pressures. The vacuum-side machinery unit 233 is a part which performs wafer transportation under low pressures reduced from the atmospheric pressure and prespecified processing within a processing chamber or chambers. And, it comprises between the atmosphere-side machinery unit 232 and vacuum-side machine unit 233 a load lock 211 which is the part that causes the pressure to go up and down between the atmospheric pressure and the vacuum pressure while simultaneously having a wafer in its inside space.

In the atmosphere-side machinery unit 232, there are load ports 201-202, aligner 234, atmospheric robot 203 and housing 204 covering a movable area of the atmospheric robot. At this load port 201, 202, a cassette which receives therein wafers to be processed is put. The atmospheric robot 203 has a hand capable of holding a wafer and operates to take a wafer received in the cassette for transportation to the interior space of load lock 211 or, adversely, take a wafer out of the load lock 211 for placing it in the cassette. This atmospheric robot 203 is able to elongate and contract a robot arm, move it up and down, and rotate it, and is further able to let it travel horizontally in the inside of housing 204. Additionally, the aligner 234 is a machine for alignment of wafer directions. It should be noted here that the atmosphere-side machinery unit 232 is one example, that the apparatus of this invention is not limited to the apparatus having two load ports and that the number of load ports may be modified to any numbers greater or less than two. In addition, the apparatus of this invention is not limited to the apparatus having a single atmosphere robot and may be arranged to have a plurality of atmosphere robots. Additionally, the apparatus of this invention is not limited to the apparatus having one aligner and may be arranged to have two or more aligners or, alternatively, to have no aligners.

In the vacuum-side machinery unit 233, there are processing chambers 205, 206, 207, 208, 209 and 210, transfer chambers 214 to 216, and intermediate chambers (also abbreviated as mid chambers in the drawings) 212-213. The processing chambers 205-210 are the parts that apply prespecified processing, such as etching, film formation and others, to a wafer(s). These are coupled to the transfer chambers 214-216 through gate valves 222, 223, 226, 227, 230 and 231, respectively. The gate valves 222, 223, 226, 227, 230 and 231 have valves which operate to open and close, thereby enabling partition and interconnection between interior spaces of treatment and transfer chambers. The transport mechanism is configured by a plurality of transport mechanism units each including the corresponding one of the transfer chambers.

The transfer chambers 214, 215 and 216 are equipped with vacuum robots 217, 218 and 219, respectively. This vacuum robot 217, 218, 219 has its hand capable of holding a wafer; thus, a robot arm is able to perform expansion/contraction, rotation and up/down movements, thereby transporting a wafer to the load lock, transferring it to a processing chamber, or sending it to an intermediate chamber.

The intermediate chamber 212, 213 is coupled between adjacent ones of the transfer chambers 214-216 and arranged to have a wafer-holding/retention mechanism. By letting the vacuum robot 217, 218, 219 put a wafer in this intermediate chamber 212, 213 and take the wafer out of the chamber, it is possible to perform delivery and receipt operations of the wafer between the transfer chambers. The intermediate chambers 212-213 are coupled to the transfer chambers 214-216 via gate valves 224, 225, 228 and 229, respectively. The gate valves 224, 225, 228 and 229 have open/close valves, thereby enabling partition and interconnection between inside spaces of treatment and transfer chambers. Note here that the vacuum-side machinery unit 233 is one example, that the apparatus of this invention is not limited to the apparatus having six processing chambers and that the number of processing chambers may be modified to any numbers greater or less than six. Additionally, although in this embodiment an explanation will be given as an apparatus with two processing chambers being coupled to one transfer chamber, the apparatus of this invention is not limited to such apparatus with two processing chambers coupled to one transfer chamber and may be arranged to connect a single processing chamber to one transfer chamber or, alternatively, three or more processing chambers to one transfer chamber. In addition, the apparatus of this invention is not limited to the apparatus having three transfer chambers: the number of such transfer chambers may be set to any given numbers greater or less than three. While in this embodiment an explanation will be given as an apparatus having gate valves between transfer chambers and intermediate chambers, these gate valves may be eliminated if necessary.

The load lock 211 is coupled to the atmosphere-side machinery unit 232 and vacuum-side machinery unit 233 via gate valves 220 and 221, respectively, thereby enabling a pressure to go up and down between the atmospheric pressure and vacuum pressure in the state that it has a wafer therein.

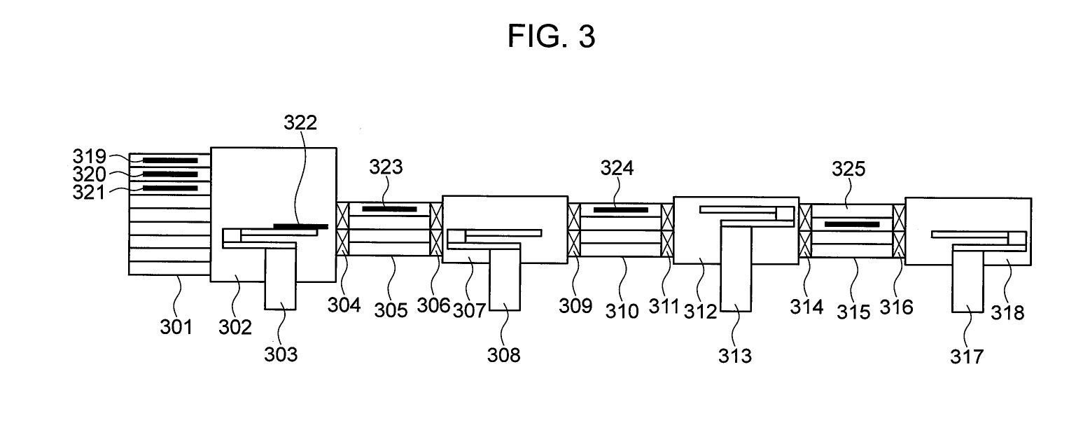

An explanation will next be given of a structure for holding a wafer with reference to FIG. 3, which shows a side view of the machinery part. The wafer is retainable in the load lock 305 and intermediate chamber 310, 315. These load lock 305 and intermediate chamber 310, 315 are arranged to hold a plurality of wafers at respective separate retainable structures (referred to hereinafter as holding stages). Although in a physical sense a given wafer can be put at any one of these holding stages, it is a typical approach to place only those wafers with their processing being not completed yet at chosen ones of the holding stages while putting only processing-completed wafers at remaining ones of the holding stages. The reason of this is as follows. Processing-completed wafers are usually with a corrosive gas for use during processing being attached thereto, causing such gas to remain at a holding stage(s). When an unprocessed wafer comes into contact with this gas, the wafer can experience alteration or transubstantiation, resulting in deterioration of wafer quality in some cases. As a consequence, in a case where the load lock is associated with, for example, four holding stages as shown in FIG. 3, one usual approach is to use two stages as unprocessed wafer folding stages while using the remaining two stages as processing-completed wafer holding stages.

It is noted here that reference numeral 301 designates a cassette which is put in the load port; numeral 302 indicates a housing covering the movable area of atmosphere robot; numeral 303 denotes an atmosphere robot; numerals 307, 312 and 318 designate transfer chambers; numerals 308, 313 and 317 denote vacuum robots; numerals 304, 306, 309, 311, 314 and 316 indicate gate valves; numerals 319, 320, 321, 322, 323, 324 and 325 indicate wafers.

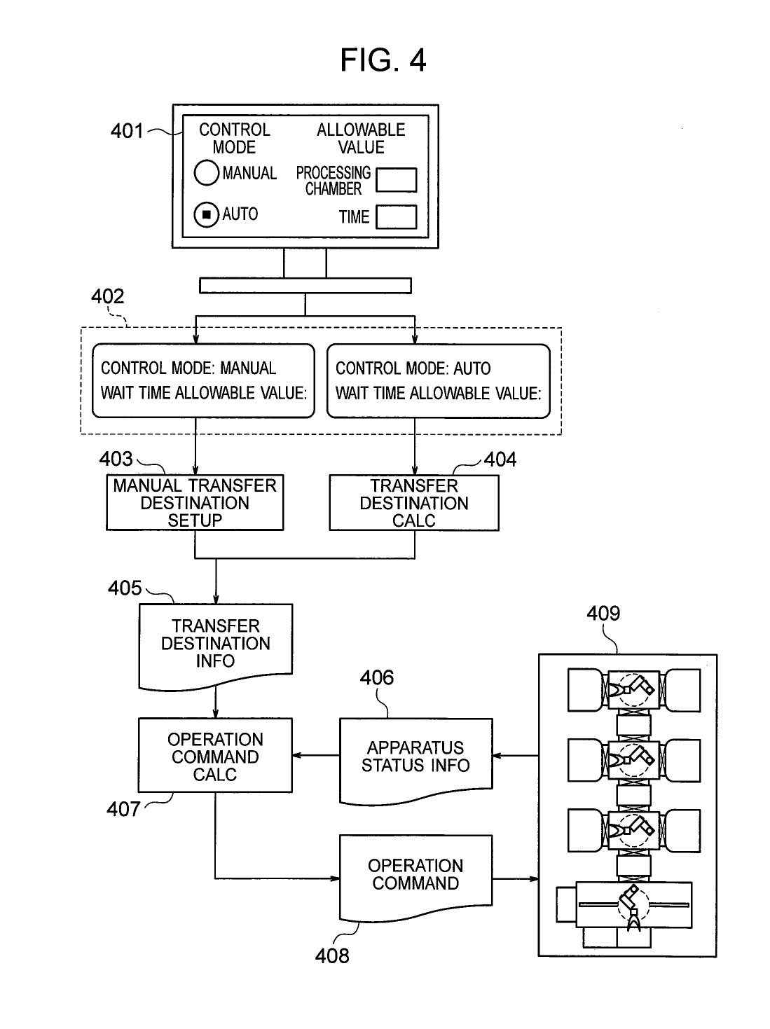

Next, an entire flow of an operation control system of the semiconductor processing apparatus of this invention will be set forth using FIG. 4. Note that a time taken for each wafer to occupy a transfer robot is different depending upon the kind of a processing step. Some process steps are such that the intended processing is completed by execution of one-time processing in a processing chamber; other process steps are such that the intended processing is completed after execution of multiple treatments. There are also differences depending on operational conditions. Some operational conditions are able to freely change a processing chamber scheduled to be used for wafer processing at any time; other operation conditions are such that the processing-scheduled processing chamber is no longer changeable once after startup of wafer transportation from an initially determined position. The operation conditions capable of freely changing the wafer processing-scheduled processing chamber at any time are such that processing conditions involving designation of the kind of a gas used for the intended processing are identical with respect to a plurality of processing chambers, with the absence of any appreciable differences in quality of processed wafers even when the processing is done in any one of the processing chambers. The operation conditions with the processing-scheduled processing chamber being no longer changeable once after the startup of wafer transportation from the initial position are such that while the processing conditions including the kind of a gas for use during treatment are the same in a plurality of processing chambers, there are a case where a procedure is employed for performing, once the processing-scheduled processing chamber is determined with respect to a wafer, fine adjustment of the processing conditions in accordance with the wafer's unique state, such as film thickness, and a case where the processing conditions such as the kind of a gas for use during processing differ depending on processing chambers. An explanation of the illustrative embodiment to be given below is under the assumption that a linear tool is arranged to deal with one-step processing only, which completes the intended processing by execution of one-time processing in a processing chamber and that, once wafer transportation is get started from the initial position, transportation is done under the operation conditions with the processing-scheduled processing chamber being no longer changeable.

From a console display screen 401, the user can selectively set the control mode to either “Manual” or “Auto.” Here, it is also possible in each processing chamber to set up the allowable value of a time taken for a wafer to stay or “wait” within processing chamber after completion of its processing. Depending on the selected control mode and the allowable value of a time taken to wait within processing chamber, the control is different in computation processing. In particular, regarding the control mode, a control mode setup unit 402 switches the computation processing of the control in accordance with the control mode designated. For instance, when “Manual” is designated for the control mode, manual transfer destination setup 403 is executed. On the other hand, if the control mode is “Auto,” transfer destination determining calculation 404 is executed.

Any one of these arithmetic processing operations 403 and 404 is the processing for determining a processing chamber serving as the transfer destination of a wafer to be loaded from now, which generates transfer destination information 405 as an output thereof. Based on the transfer destination information 405 and apparatus status information 406, an operation command 408 is calculated in operation command calculation 407. Based on it, a machinery part 409 performs its operation. Then, by performing such operation, the internal apparatus status varies, causing the apparatus status information 406 to be updated. Then, again calculates the operation command 408 is again calculated in the operation command calculation 407 based on the transfer destination information 405 and apparatus status information 406. In responding thereto, the machinery part 409 performs its next operation.

Additionally, the arithmetic processing 404 for determining a transfer destination processing chamber in an automated manner is executed every time when the transfer destination of a new object to be processed is determined, thereby updating the transfer destination information 405. For example, when the atmosphere robot has completed the transportation of a wafer and then goes into a state capable of performing an operation with respect to a new wafer, the transfer destination of such new wafer is calculated.

As the present invention relates to efficient control methodology in the case of the control mode being set to “Auto,” a control method in the case of its control mode being set to “Auto” will be described below. Hence, in a description below, calculation for transfer destination determination refers to the transfer destination calculation 404.

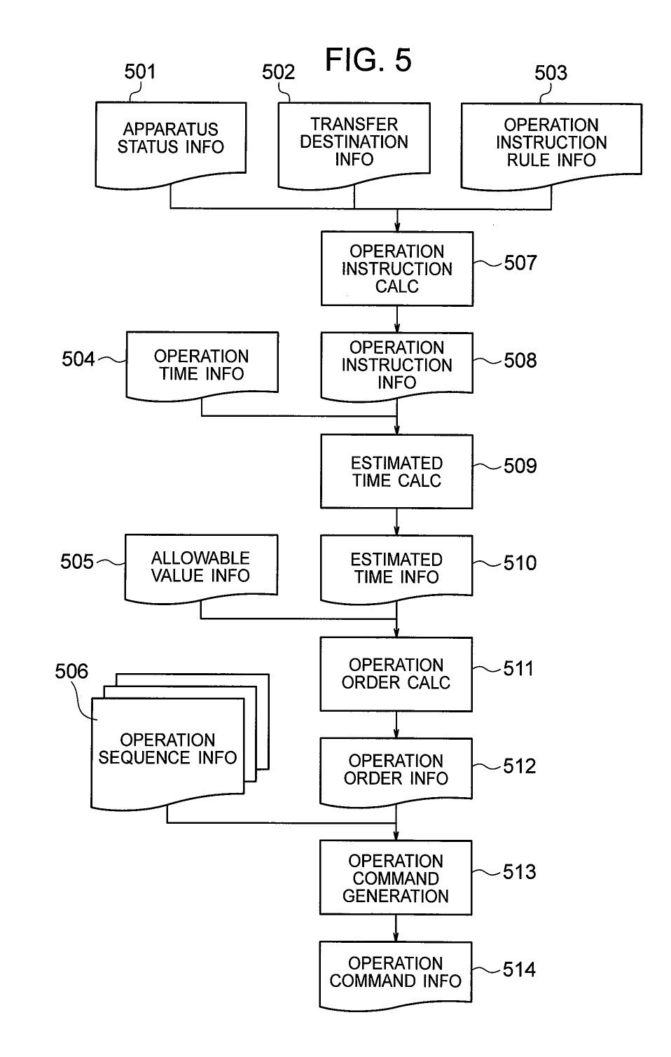

First of all, the operation command calculation 407 shown in FIG. 4 will be described in detail with reference to FIG. 5. FIG. 5 is a diagram showing in detail the relationship between the processing of operation command calculation 407 and input/output information. The operation command calculation 407 includes four arithmetic processing steps: operation instruction calculation 507, estimated time calculation 509, operation order calculation 511 and operation command generation 513.

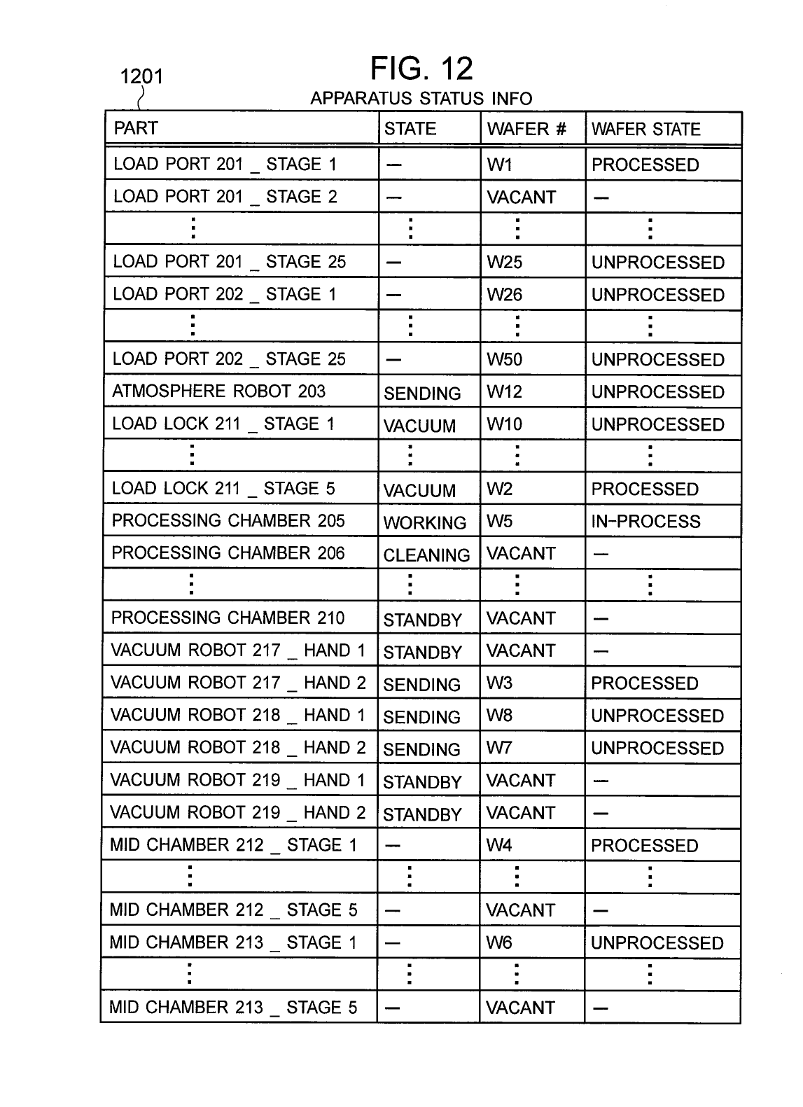

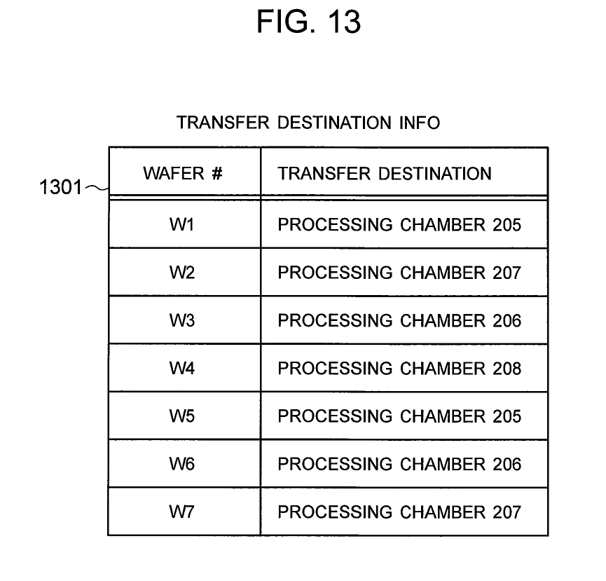

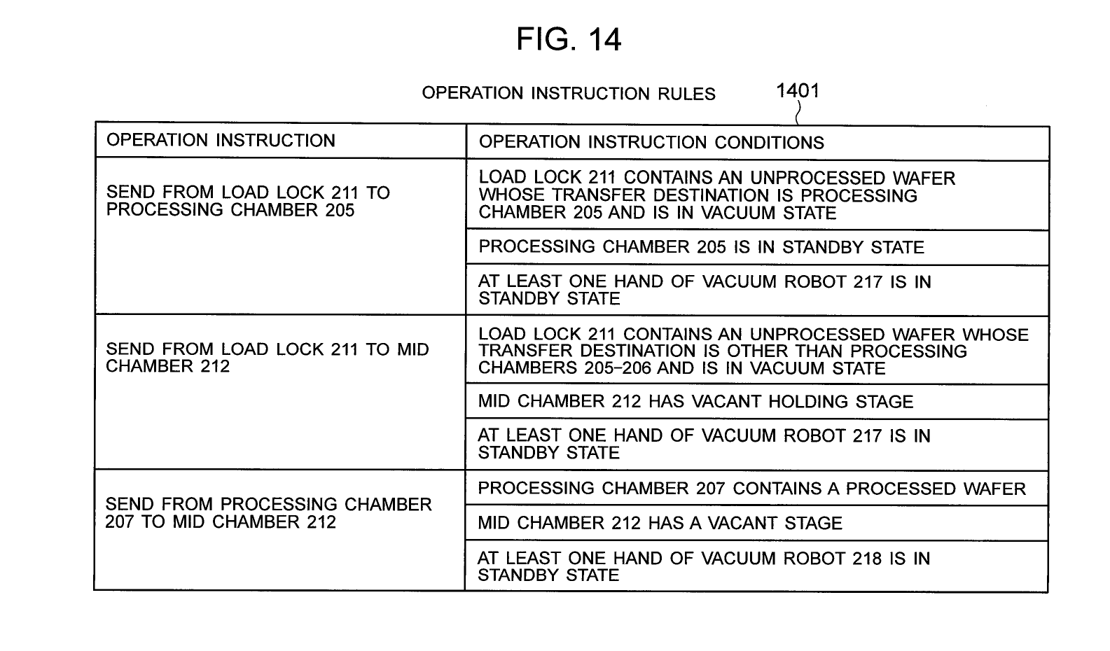

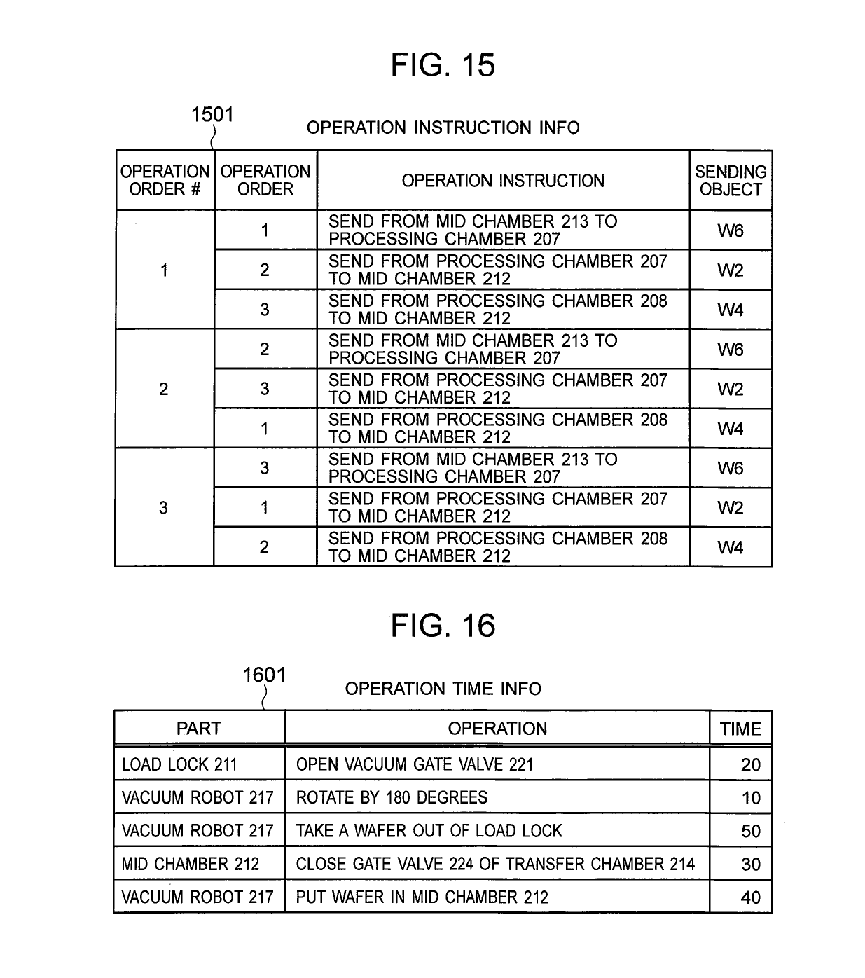

The operation instruction calculation 507 is the one that inputs apparatus status information 501, transfer destination information 502 and operation instruction rule information 503 and outputs operation instruction information 508. The apparatus status information 501 is information as exemplarily shown in FIG. 12 and is the information that represents a present status of each part, the number of a wafer staying therein, and the state of processing. For example, data “Part: Load lock 221_Stage 1, State: Vacuum, Wafer No.: W11, Wafer State: Unprocessed” indicates a present state of the first stage of the holding stages of load lock 221 and means the following: the load lock is in a vacuum state; a wafer with its number W11 is retained; and, such wafer W11 is an unprocessed wafer. The transfer destination information 502 is information exemplified in FIG. 13 and is the information representing a transfer destination processing chamber of each wafer. The operation instruction rule information 503 is information exemplified in FIG. 14 and is the information describing an operation instruction and conditions for execution of such operation instruction. For example, an instruction “Send from Load Lock 211 to Intermediate Chamber 212” means that the instruction is done when the following conditions are met at a time: “an unprocessed wafer whose transfer destination is other than the processing chambers 205-206 is found in the load lock 211 and, simultaneously, load lock 211 is in a vacuum state,” “there is a vacant holding stage in the intermediate chamber 212,” and “at least one hand of the vacuum robot 217 is in standby state.” The operation instruction information 508 is information exemplified in FIG. 15 and is the information having a transportation operation instruction, to-be-processed wafer number, operation order number and sequential order of respective operation instructions. The operation instruction calculation 507 includes the steps of referring to the apparatus status information 501 and transfer destination information 502, extracting an operation instruction which satisfies all of the operation instruction conditions of operation instruction rule information 503, and outputting such operation instruction as the operation instruction information 508.

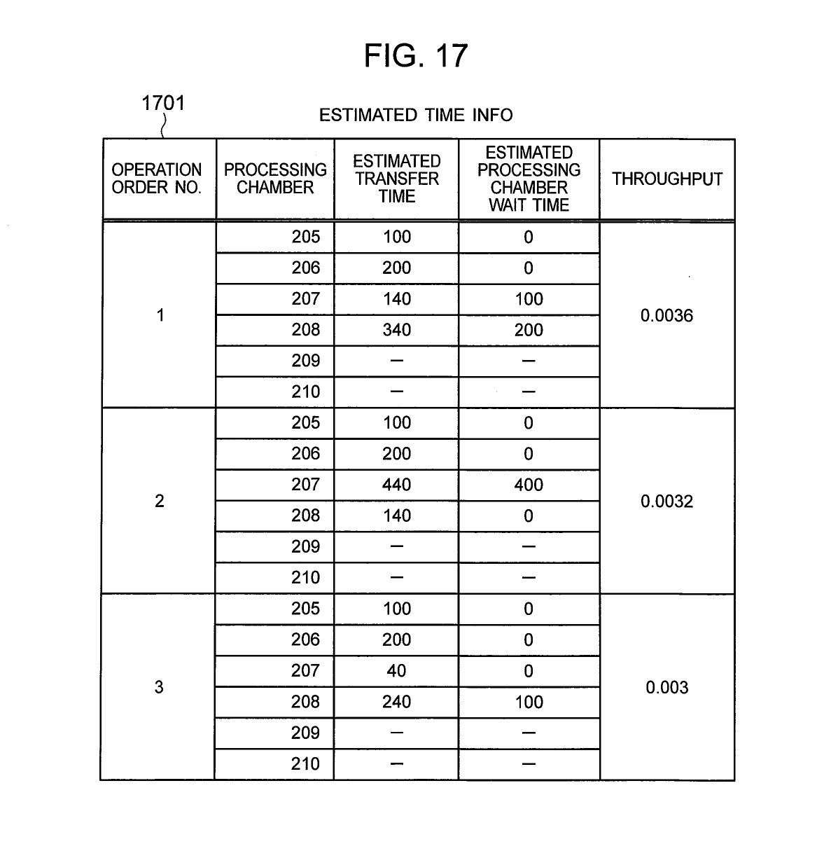

The estimated time calculation 509 is processing which uses the apparatus status information 501, transfer destination information 502, operation time information 504 and operation instruction information 508 to output estimated time information 510. The operation time information 504 is information exemplified in FIG. 16 and is the information representing time lengths required for operations of those parts within the apparatus, such as transfer robots, load lock, etc. The estimated time information 510 is information exemplified in FIG. 17 and is the information representing, per operation order, a throughput and an estimated time taken to wait within a processing chamber after completion of the processing in each processing chamber.

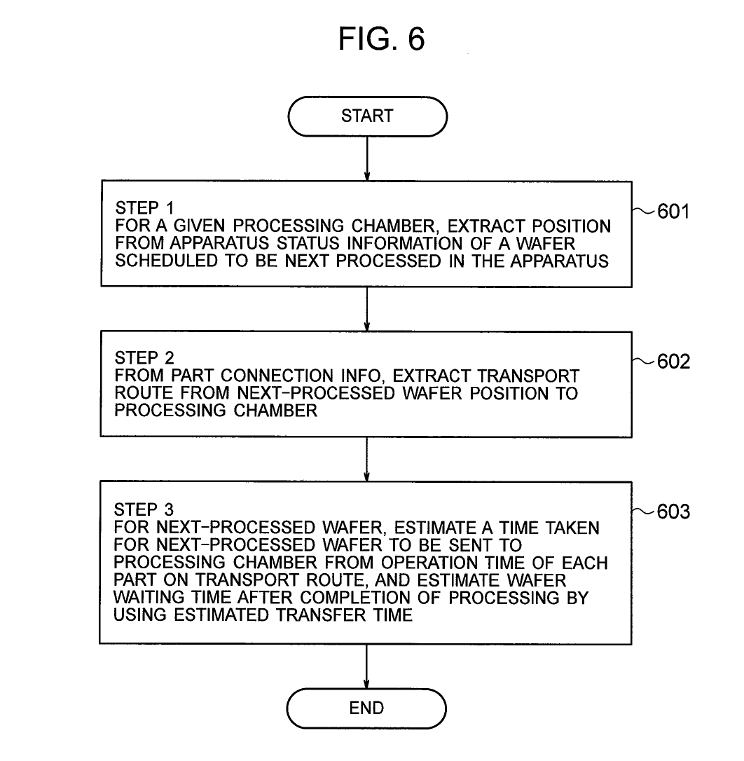

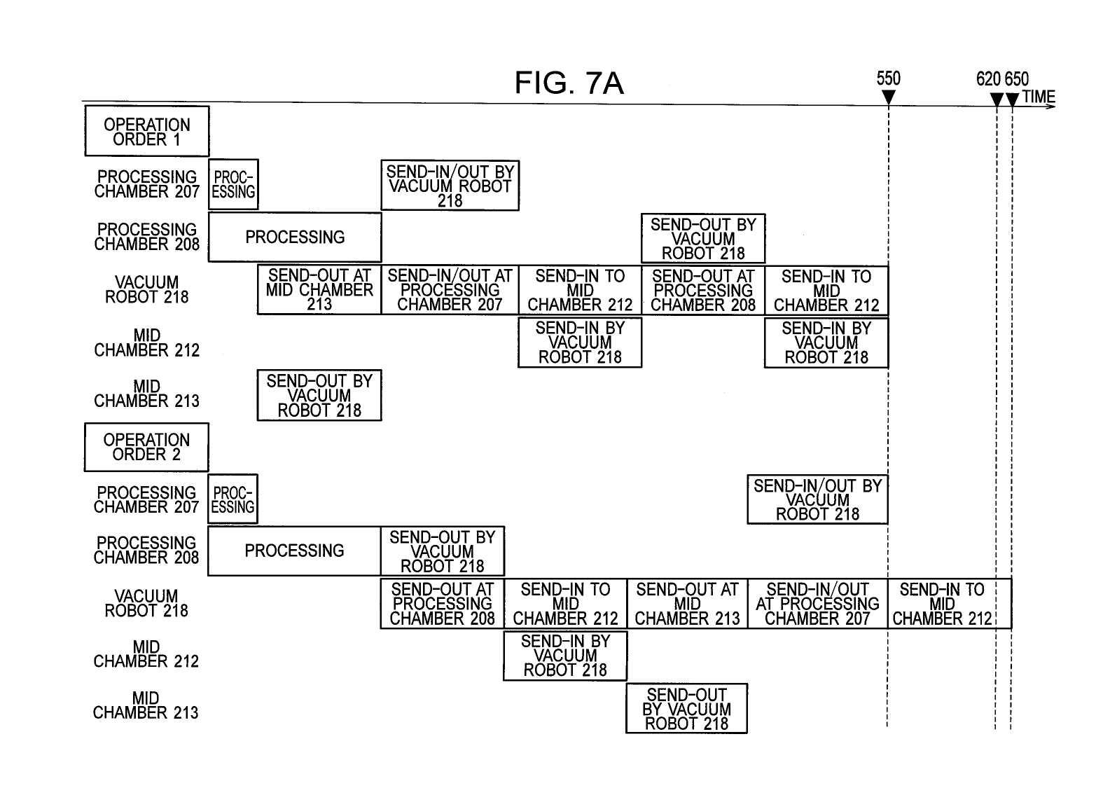

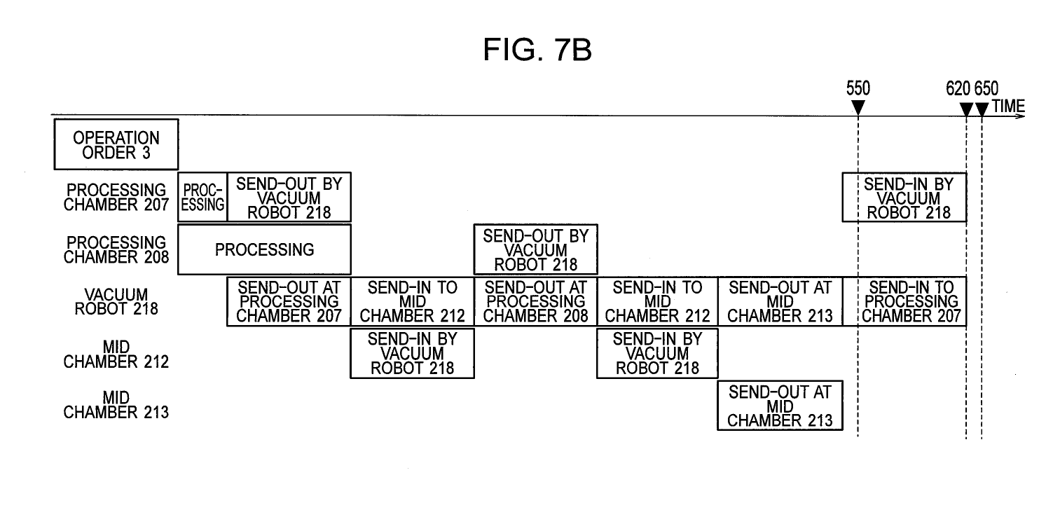

Here, the estimated time calculation shown in FIG. 5 will be described in greater detail with reference to a flowchart of FIG. 6. Firstly, at processing step 601, a present position of a wafer which is scheduled to be next processed is acquired. Next, at processing step 602, a transportation route of from the present position of the next-processed wafer to a processing chamber is acquired. At step 603, the operation time information is used to estimate a transfer time with respect to a given part existing on the transfer route. Using the estimated transfer time, a wafer waiting time after completion of its processing is estimated. In this embodiment, simulation is used as one example of the transfer time calculation technique. The information shown in FIG. 17 is a result of calculation by simulation. It assumes a plurality of operation orders and estimates a time taken for transportation to a respective processing chamber, a processing chamber waiting time spanning from completion of wafer processing to takeoff therefrom, and a throughput. FIGS. 7A and 7B are diagrams each showing a Gantt chart in the case of operation instructions being made relying on respective operation orders 1 to 3. Gantt chart is the one that represents a time zone of each part rendered operative by a block while letting time be plotted along the lateral axis. FIGS. 7A and 7B show three different operation orders each calculated by simulation, that is, FIG. 7A shows the operation orders 1 and 2 and FIG. 7B shows the operation order 3. It indicates the wafer processing in processing chamber 207, 208 and the loading/unloading of processing-completed wafers in relation to the operation of vacuum robot 218 and the intermediate chamber 212, 213. In actual applications, those to be calculated by simulation are not limited to three ways, and the simulation may be applied to a large number of combinations of operations.

The throughput of the apparatus is calculated from the number of wafers capable of being processed per unit time. As can be seen from FIGS. 7A and 7B, the throughput is calculated from the termination time of each operation and the number of wafers processed. Since the processed wafer number in Gantt chart of FIGS. 7A and 7B is two, the throughput of each operation order is calculable by dividing the processed wafer number by a time taken up to the operation completion, resulting in the operation order 1 being equal to 0.0036, the operation order 2 being equal to 0.0032, and the operation order 3 being equal to 0.003.

Examples of the transfer time calculation method other than the simulation include a technique for using a total value of respective operation time periods. Alternatively, in the case of the transfer time being computed, when there is a part which has already been occupied by another wafer, a time taken up to completion of such operation is added thereto whereby a resultant value may be regarded as the transfer time.

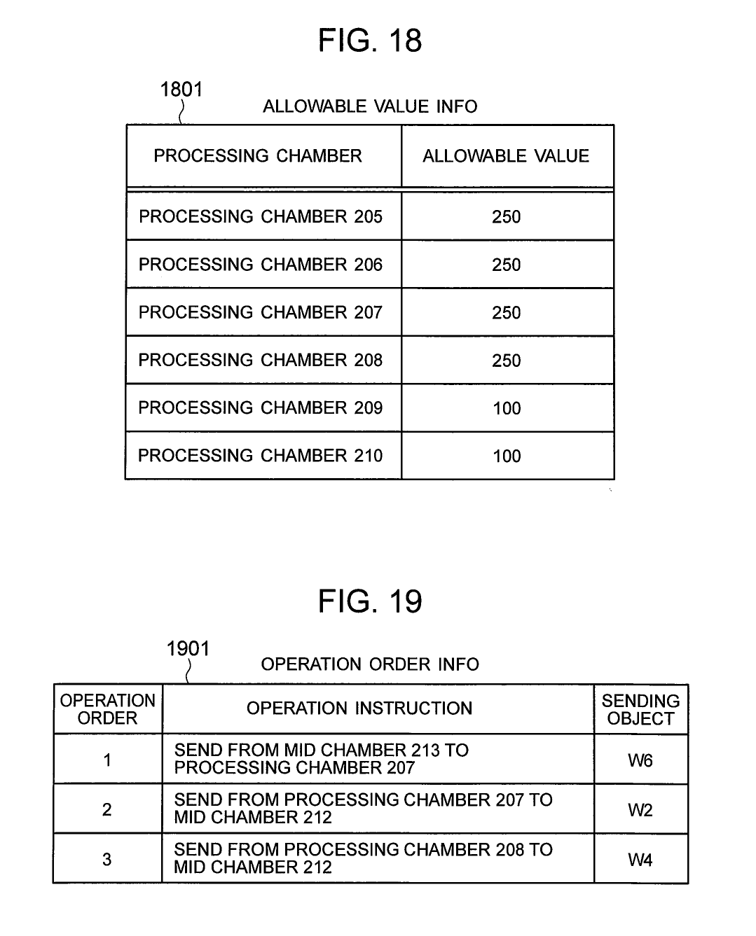

The operation order calculation 511 is the processing that uses the estimated time information 510 and allowable value information 505 to calculate operation order information 512. The allowable value information 505 is information as exemplarily shown in FIG. 18 and is the information representing, per processing chamber, an allowable time taken for a wafer to wait within a processing chamber after completion of its processing. The operation order information is information exemplified in FIG. 19 and is the information representing an order of operations, an operation instruction and an object being transported.

From the estimated time information, an operation order which is one of those operation orders with their processing-chamber waiting times falling within the allowable time and which exhibits the highest throughput is output; in the information shown in FIGS. 17 and 18, the operation order 1 is output.

Additionally, when taking into consideration a simulation result, the following operation may also be performed in order to improve the throughput. More specifically, in cases where it is possible to unload a wafer from a processing chamber while satisfying the allowable value, when a processing-completed wafer is present in a processing chamber, and when, in a transfer mechanism unit coupled to this processing chamber, there is a processing-uncompleted or “unprocessed” wafer whose next transfer destination is the processing chamber in an intermediate chamber coupled to the transport mechanism, the unprocessed wafer is unloaded with priority over the processed wafer staying within the processing chamber, thereby improving the throughput.

In addition, in case a time which is estimated to be taken for transportation to a processing chamber goes over the allowable value of the waiting time of processed wafer, the unloading of a processed wafer takes priority over the unloading of an unprocessed wafer as far as a chamber which is the wafer's next transfer destination is in an acceptable state, whereby unwanted excess or “overrun” of the allowable value of the wafer's wait time may be avoided. Also note that in practical operations, an approach may be employed for preventing a presently performed operation from halting (i.e., avoiding deadlock) even upon excess of the allowable value of the wafer's waiting time and for giving the best possible priority to the unloading of a processed wafer(s) over the unloading of unprocessed wafers.

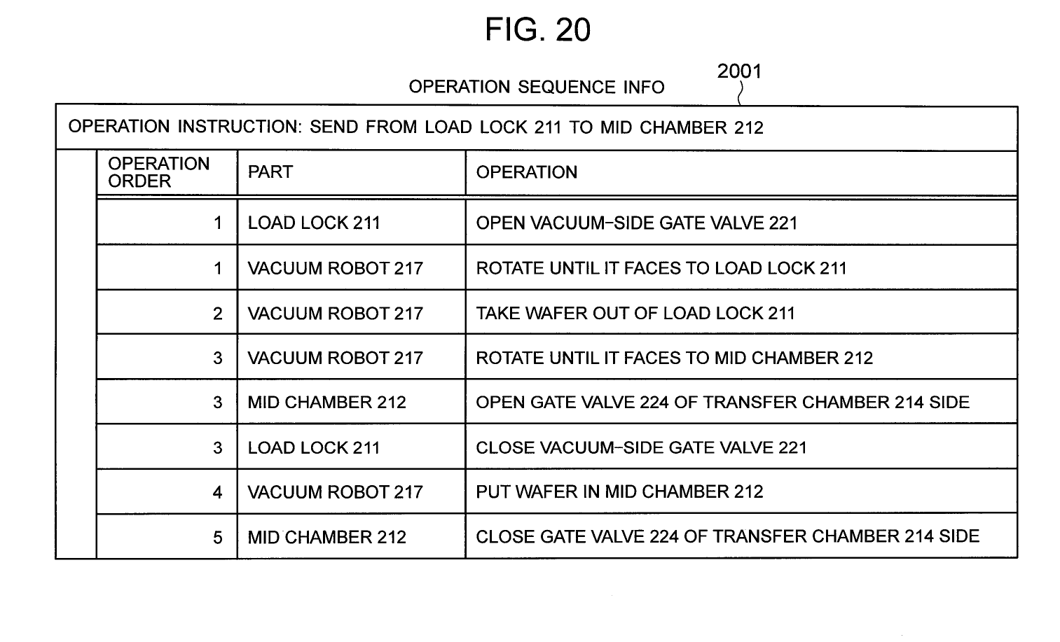

Next, the operation command generation 513 is the one that inputs the operation instruction information 508, operation order information 512 and operation sequence information 506 and outputs an operation command 514, which is then transmitted to the machinery part. The operation sequence information 506 is information as exemplarily shown in FIG. 20. This is the one that describes, concerning an operation instruction, detailed operation contents of respective parts, such as operations of atmospheric and vacuum robots, open/close operations of the gate valves of the load lock and intermediate and processing chambers, and an operation of a pump used to perform vacuuming of the load lock, thereby to mean that these operations with their numbers described in the operation order information are sequentially executed in such a manner that one with a smaller number precedes another with a larger number. This operation sequence information 506 is defined for each operation instruction independently. Optionally, if an operation activatable state is established, the operation may be get started even when the operation having a smaller number is not completed yet.

In the operation command generation 513, regarding an operation instruction contained in the operation instruction information 508, operation sequence data of corresponding instructions are extracted from the operation sequence information 506 in an ascending order of their numbers indicated in the operation order information 512 and then sent as an operation command to the machinery part in the ascending order of the numbers of such operation sequence data.

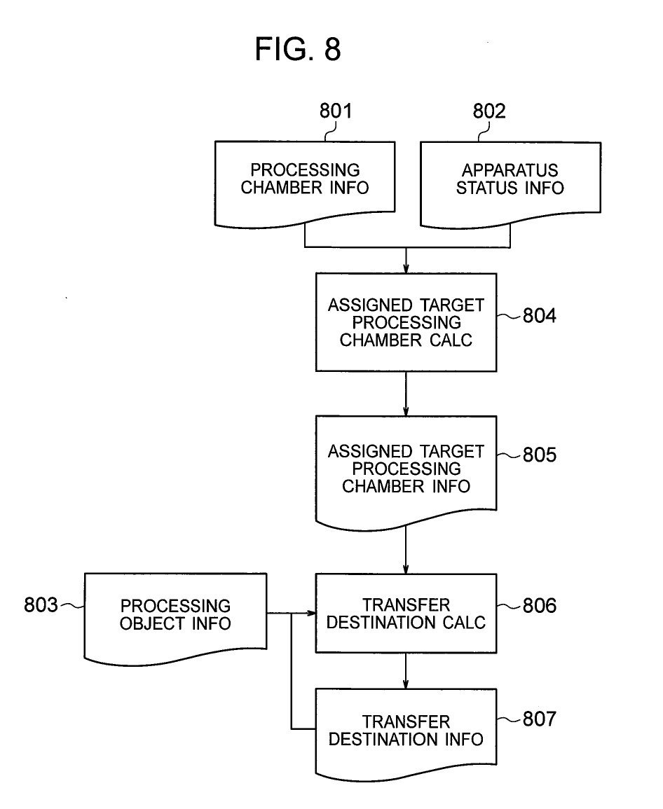

An explanation will next be given as one embodiment in the transfer destination-determining calculation 404 shown in FIG. 4 with reference to FIG. 8. The transfer destination determination calculation 404 consists essentially of two arithmetic processing steps: assigned target processing chamber information calculation 804 and transfer destination calculation 806.

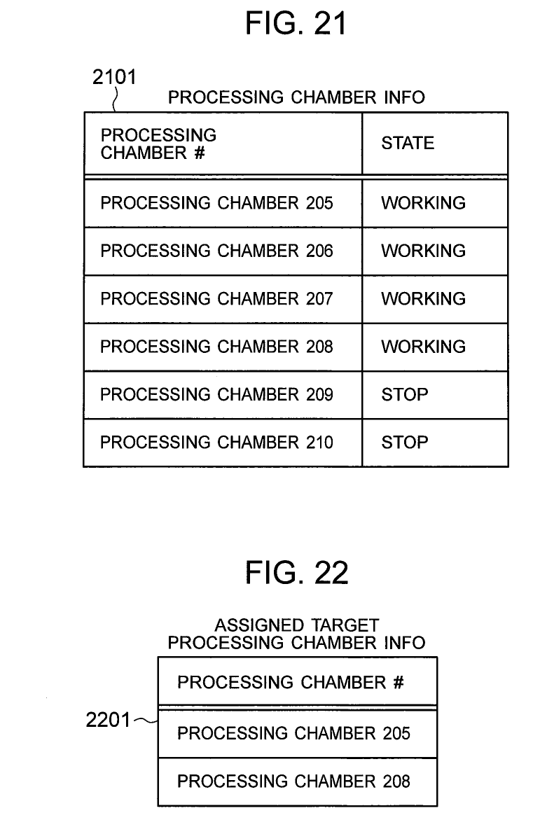

The assigned target processing chamber calculation 804 is the one that inputs the processing chamber information 801 and apparatus status information 802 and outputs assigned target processing chamber information 805. The processing chamber information 801 is information as exemplarily shown in FIG. 21 and the information that represents a working situation of each processing chamber. When the status is set to “Working,” it means the state capable of performing processing; if the status is “Stop,” it means the state incapable of performing any processing. The assigned target processing chamber calculation 804 is the processing for extracting a transportable processing chamber. The assigned target processing chamber information 805 is information exemplified in FIG. 22 and the information with a list of those processing chambers which become candidates of the wafer transfer destination during computation of such transfer destination. One example is a technique for determining a given processing chamber with its status being set to “Working” to be the assigned target processing chamber. This extraction is one example only: other extraction methods may be used to extract the assigned target processing chamber.

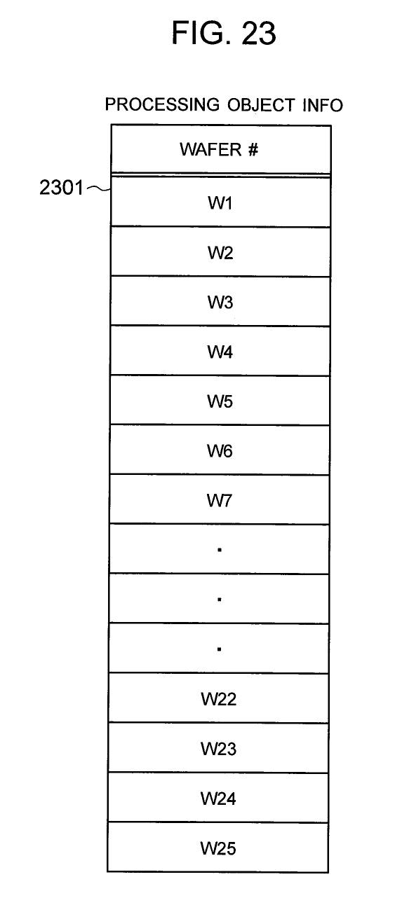

The transfer destination calculation 806 is the processing that inputs processing object information 803 and transfer destination information 801 plus assigned target processing chamber information 805 and updates transfer destination information 807. The processing object information 803 is information exemplified in FIG. 23 and the information that describes therein wafer numbers for identification of certain wafers to be processed.

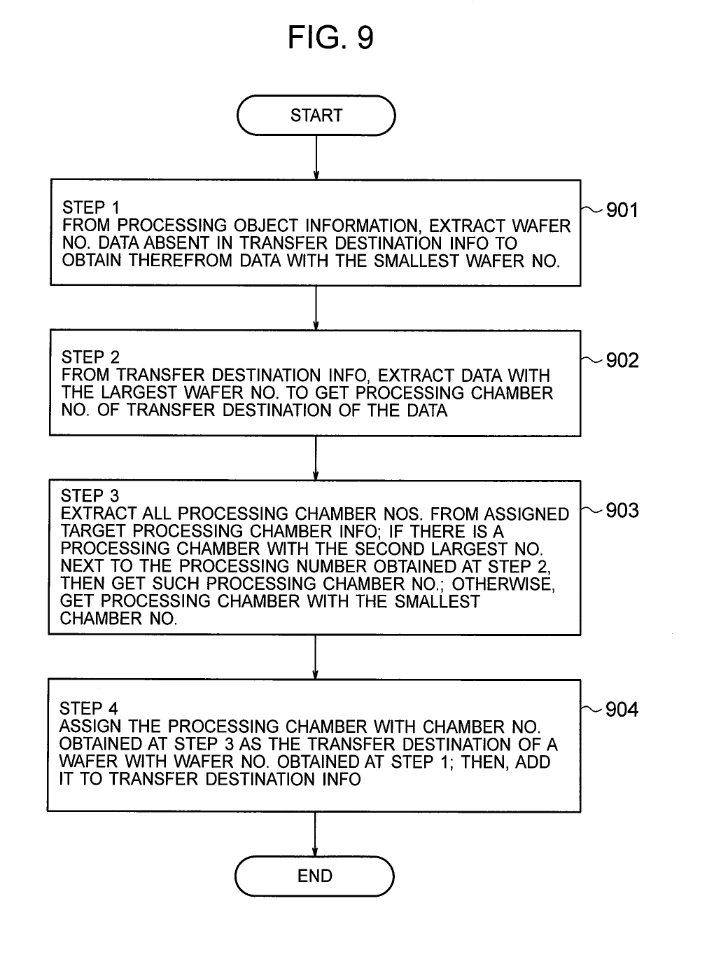

A detailed explanation will next be given of computation processing of the transfer destination calculation 806 shown in FIG. 8, by using a flowchart of FIG. 9. The transfer destination calculation 806 is the processing for determining a processing chamber which is the destination of a wafer(s) to be loaded into the apparatus from now. Firstly, at processing step 901, the wafer number of a wafer which is to be loaded into the apparatus from now is acquired. Practical processing thereof includes extracting wafer number data being absent in the transfer destination information from the processing object information, acquiring therefrom a specific one having the smallest wafer number, and determining it as the wafer to be loaded into the apparatus from now. Then, at processing step 902, an operation is performed for extracting from the transfer destination information specific data with the largest wafer number, and obtaining a processing chamber for use as the transfer destination of such data. Next, at processing step 903, an operation is performed to extract all the processing chamber numbers contained in the assigned target processing chamber information, and find therefrom a processing chamber number which is larger than the processing chamber numbers obtained at step 902, and, if such is found, determine as the transfer destination processing chamber a processing chamber with the smallest processing chamber number among the processing chamber numbers larger than the processing chamber number obtained at step 902. If there are no processing chamber numbers larger than the processing chamber number obtained at step 902 then determine as the transfer destination processing chamber a processing chamber with the smallest processing chamber number among all the processing chamber numbers indicated in the assigned target processing chamber information. Finally, at processing step 904, the transfer destination processing chamber acquired at step 903 is assigned as the wafer transfer destination processing chamber obtained at step 901, which is then added to the transfer destination information. It is noted that the transfer destination determination algorithm as set forth in this embodiment is one example and is not to be construed as limiting the present invention. Other algorithms may alternatively be employed as far as these are arranged to input the assigned target processing chamber information calculated based on unprocessed wafer quantity information and compute a wafer transfer destination.

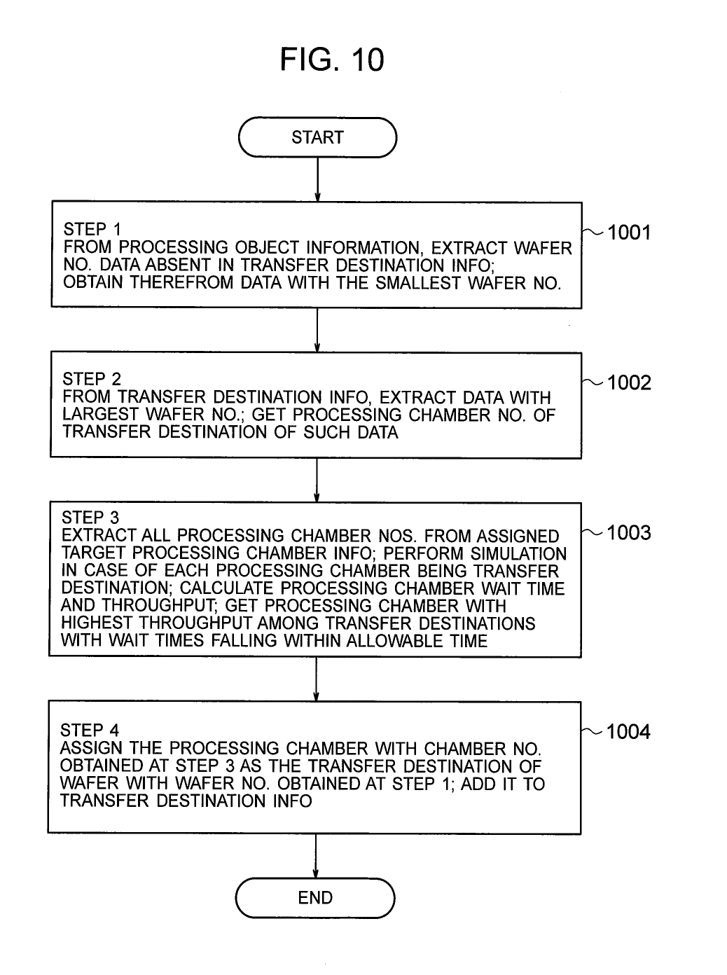

Another embodiment in the transfer destination calculation 404 shown in FIG. 4 will be described using a flow diagram of FIG. 10. First, at processing step 1001, the wafer number of a wafer to be loaded into the apparatus from now is acquired. Practical processing thereof includes extracting wafer number data being absent in the transfer destination information from the processing object information, acquiring therefrom a specific one having the smallest wafer number, and determining it as the wafer to be loaded into the apparatus. Then, at processing step 1002, an operation is performed for extracting from the transfer destination information specific data with the largest wafer number and obtaining a processing chamber for use as the transfer destination of such data. Next, at processing step 1003, an operation is done to extract all the processing chamber numbers existing in the assigned target processing chamber information and for executing simulation in the case of each processing chamber being assigned as the transfer destination. In a similar way to that shown in FIG. 7, as a result of the simulation, there are calculated per each transfer destination a throughput and a time taken for wafer to wait within processing chamber after completion of its processing, thereby acquiring a processing chamber with the highest throughput among those transfer destinations with their wait time lengths less than or equal to the allowable value. Finally, at processing step 1004, the transfer destination processing chamber acquired at step 1003 is assigned as the wafer transfer destination processing chamber obtained at step 1001, which is then added to the transfer destination information. In short, this is a computation method for estimating the waiting time within a processing chamber upon determination of the transfer destination and for outputting the transfer destination in such a manner as to remain not greater than the allowable value.

Note here that the apparatus status information 501 described in conjunction with FIG. 6 and processing chamber information 801 discussed using FIG. 8 are information resulting from monitoring of the machinery part and are subjected to updating on a real time basis. The processing object information 803 is downloaded by the host computer when a cassette containing therein wafers under processing arrives at the load port.

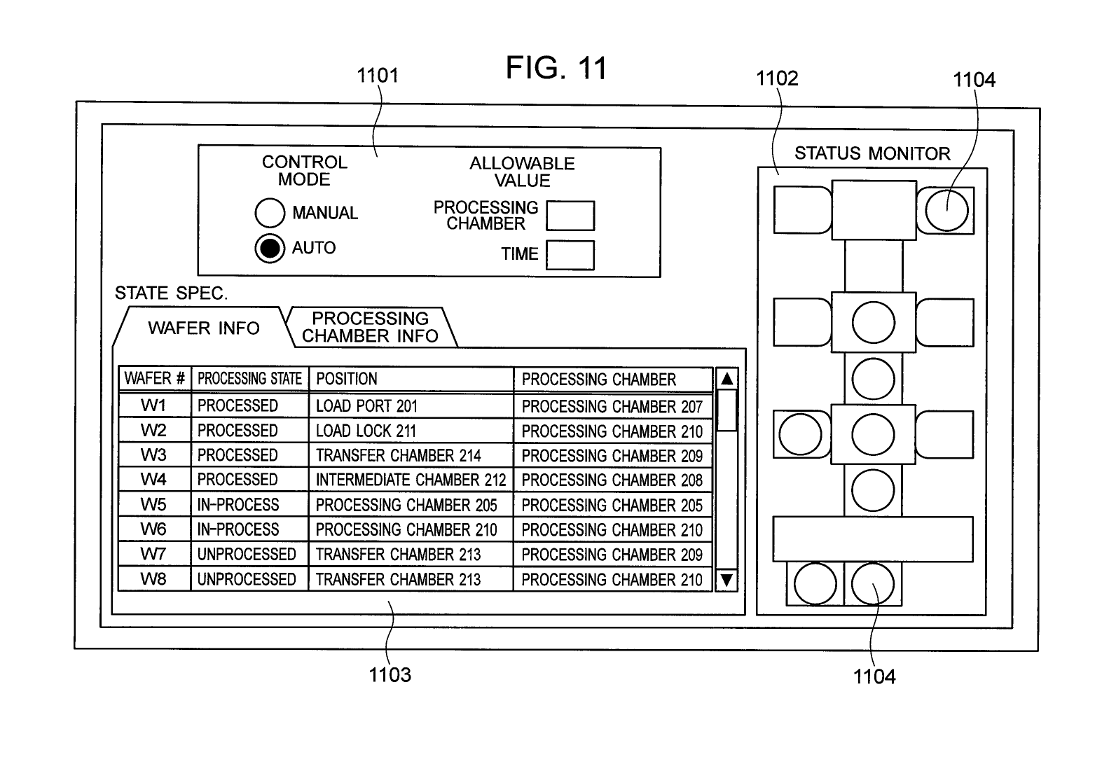

Lastly, the display screen of console terminal 103 shown in FIG. 1 will be explained using FIG. 11. The console terminal 103 has an input unit and an output unit. The input unit includes a key board, mouse and touch pen or the like. The output unit has a display panel with screen. On the display screen, there are an area 1101 for selecting a control method, an area 1102 for visually displaying a brief summary of apparatus status, and an area 1103 for displaying detailed data of the apparatus status. In the control method selection area 1101, the user can select his or her preferred mode of control method, i.e., “Manual” or “Auto.” Upon selection of “Auto” as the control method, it becomes possible to further select the presence or absence of processing chamber uncertainty handleability. The allowable value of the wait time of a processing-completed wafer also is inputtable per processing chamber. In the apparatus status summary displaying area 1102, a pictorial representation of the apparatus system and present positions of wafers are visually displayed so as to enable the user to readily recognize the individual wafer is presently at which location in the system. As wafers move, their display positions are changed accordingly. Those depicted by circular forms within the area 1102 in FIG. 11 represent wafers 1104. Additionally, in the area 1103 for displaying detailed data of apparatus status, detailed states of those wafers staying in the apparatus and detailed states of processing chambers and transport mechanisms. It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising:
a load lock for loading into a vacuum side an object to be processed which is put on an atmosphere side;
a plurality of transport mechanism units, disposed on the vacuum side, each including a vacuum robot for performing delivery/receipt and transportation of the object to be processed;
a plurality of processing chambers coupled to said plurality of transport mechanism units, for applying predetermined processing to the object to be processed;
an intermediate chamber for coupling adjacent ones of said transport mechanism units and for relaying and mounting the object to be processed;
a retention mechanism unit provided in said load lock and said intermediate chamber, for holding a plurality of objects to be processed; and
a control unit for controlling delivery/receipt and transportation of the object to be processed, wherein
said control unit determines a transfer chamber which transfers the object to be processed and an operation order of said transport mechanism units based on a time permitted for the to-be-processed object to wait within one of said processing chambers after completion of processing thereof.

2. The vacuum processing apparatus according to claim 1, said apparatus further comprising:
an input unit capable of inputting an allowable value of the time permitted for the to-be-processed object to wait within the processing chamber after completion of its processing, wherein said control unit determines a transfer operation of the to-be-processed object based on the allowable value of a waiting time of the to-be-processed object within said processing chamber, which value is from said input unit.

3. The vacuum processing apparatus according to claim 1, wherein said control unit calculates by simulation a processing throughput of the to-be-processed object and determines based on this throughput both the transfer chamber which transfers the to-be-processed object and the operation order of said transport mechanism units.

4. The vacuum processing apparatus according to claim 1, wherein in cases where it is possible to unload the to-be-processed object sooner than the time permitted for the to-be-processed object to wait within said processing unit after completion of its processing, when a processing-completed to-be-processed object which is one of the to-be-processed objects is present within said processing chamber and when, in a transport mechanism unit coupled to this processing chamber, a to-be-processed object which remains unprocessed and whose next transfer destination is this processing chamber exists within said intermediate chamber coupled to the transport mechanism unit, said control unit unloads the to-be-processed object which remains unprocessed while giving priority thereto over the processing-completed to-be-processed object staying within said processing chamber.

5. The vacuum processing apparatus according to claim 2, wherein said control unit estimates a time taken for transfer to said processing chamber and, in cases where the estimated transfer time exceeds the allowable value of the waiting time of the to-be-processed object with its processing completed, causes the transport mechanism unit to prioritize unloading of the to-be-processed object with its processing completed over unloading of the to-be-processed object remaining unprocessed as far as a chamber which is the next transfer destination of the to-be-processed object is in a state capable of accepting said to-be-processed object.

6. The vacuum processing apparatus according to claim 1, wherein regarding the operation order of the plurality of transport mechanism units, said control unit calculates a time taken for the to-be-processed object to wait within said processing chamber after completion of its processing and selects an operation order of said transport mechanism units which prevents the calculated time from exceeding the time permitted for the to-be-processed object to wait within said processing chamber after completion of its processing.

7. A vacuum processing method for processing objects to be processed in a vacuum processing apparatus having a load lock for loading into a vacuum side an object to be processed which is put on an atmosphere side, a plurality of transport mechanism units disposed on the vacuum side and each including a vacuum robot for performing delivery/receipt and transportation of the object to be processed, a plurality of processing chambers coupled to said transport mechanism units for applying predetermined processing to the object to be processed, an intermediate chamber for coupling adjacent ones of said transport mechanism units and for relaying and mounting the object to be processed, and a retention mechanism unit provided in said load lock and said intermediate chamber for holding a plurality of objects to be processed, said method comprising the steps of:
setting a time permitted for the to-be-processed object to wait within said processing chamber after completion of its processing; and
determining, based on the time thus set up, an operation order of transfer chambers for transportation of the to-be-processed object and said transport mechanism units.

8. The vacuum processing method according to claim 7, further comprising the steps of:
calculating by simulation a processing throughput of the to-be-processed object; and
determining based on the throughput a transfer chamber for transferring the to-be-processed object and an operation order of said transport mechanism units.

9. The vacuum processing method according to claim 7, wherein said step of determining an operation order of transfer chambers for transportation of the to-be-processed object and said transport mechanism units performs processing which follows: in cases where it is possible to unload the to-be-processed object sooner than the time permitted for the to-be-processed object to wait within said processing unit after completion of its processing, when a processing-completed to-be-processed object which is one of the to-be-processed objects is present within said processing chamber and when, in a transport mechanism unit coupled to this processing chamber, a to-be-processed object which remains unprocessed and whose next transfer destination is this processing chamber exists within said intermediate chamber coupled to the transport mechanism unit, the to-be-processed object which remains unprocessed is unloaded while having priority over the processing-completed to-be-processed object staying within said processing chamber.

10. The vacuum processing method according to claim 7, wherein said step of determining an operation order of transfer chambers for transportation of the to-be-processed object and said transport mechanism units includes:
estimating a time taken for transfer to said processing chamber; and
in cases where the estimated transfer time exceeds the allowable value of the waiting time of the to-be-processed object with its processing completed, causing the transport mechanism unit to prioritize unloading of the to-be-processed object with its processing completed over unloading of the to-be-processed object remaining unprocessed as far as a chamber which is the next transfer destination of the to-be-processed object is in a state capable of accepting said to-be-processed object.

11. The vacuum processing method according to claim 7, wherein regarding the operation order of the plurality of transport mechanism units, said step of determining an operation order of transfer chambers for transportation of the to-be-processed object and said transport mechanism units includes:
calculating a time taken for the to-be-processed object to wait within said processing chamber after completion of its processing; and
selecting an operation order of said transport mechanism units which prevents the calculated time from exceeding the time permitted for the to-be-processed object to wait within said processing chamber after completion of its processing.
